(19) United States
(12) Patent Application Publication
(10) Pub. No.: US 2024/0191389 A1
(43) Pub. Date: Jun. 13, 2024

(54) METHOD OF MANUFACTURING SILICON SINGLE CRYSTAL AND METHOD OF MANUFACTURING WAFER USING THE SAME

(71) Applicant: Samsung Electronics Co., Ltd., Suwon-si (KR)

(72) Inventors: Hyeyun PARK, Suwon-si (KR); Inji LEE, Suwon-si (KR)

(73) Assignee: Samsung Electronics Co., Ltd., Suwon-si (KR)

(21) Appl. No.: 18/522,817

(22) Filed: Nov. 29, 2023

(30) Foreign Application Priority Data
Dec. 9, 2022 (KR) 10-2022-0171863

(51) Int. Cl. C30B 15/04; C30B 15/20; C30B 29/06; C30B 33/00

(52) U.S. Cl. CPC C30B 15/04; C30B 15/20; C30B 29/06; C30B 33/00

(57) ABSTRACT

A method of manufacturing a silicon single crystal includes preparing a silicon melt and growing the silicon single crystal based on co-doping boron and phosphorus into the silicon melt. The growing of the silicon single crystal includes controlling, a doping concentration ratio, which is a ratio of an initial concentration of phosphorus to an initial concentration of boron, to be a particular ratio and controlling the initial concentration of boron to be within a range of about 8.0E12 atom/cm³ to about 1.5E13 atom/cm³.

### CROSS-REFERENCE TO RELATED APPLICATION

This application is based on and claims priority under 35 U.S.C. § 119 to Korean Patent Application No. 10-2022-0171863, filed on Dec. 9, 2022, in the Korean Intellectual Property Office, the disclosure of which is incorporated by reference herein in its entirety.

### BACKGROUND

The inventive concepts herein relate to methods of manufacturing a silicon single crystal. More particularly, the present inventive concepts relate to methods of manufacturing a p-type silicon single crystal including a dopant, and methods of manufacturing a wafer using the same.

Recently, as semiconductor devices have been highly integrated, the quality of a wafer used to realize the semiconductor devices has a great influence on the yield and the reliability of the semiconductor devices. The quality of a semiconductor wafer depends on how many defects happen throughout a silicon single crystal growth process, in which a silicon single crystal ingot is produced, and a wafer processing process, in which the silicon single crystal ingot is sliced and at least one major surface of the sliced silicon single crystal ingot is processed into a mirror-like shape.

Recently, there has been an increasing demand for a silicon single crystal having a high resistivity of 1000 Ω·cm as the quality of a silicon single crystal produced by the Czochralski method, is highly demanded, and therefore, technological development to meet the demand is required.

### SUMMARY

Some example embodiments of the inventive concepts may include a method of manufacturing a silicon single crystal, wherein the initial concentration of boron doped into the silicon single crystal is controlled to be within a range of about 8.0E12 atom/cm³ to about 1.5E13 atom/cm³. Additionally, some example embodiments of the inventive concepts may provide the method of manufacturing a silicon single crystal, wherein a doping concentration ratio, which is a ratio of an initial concentration of phosphorus to an initial concentration of boron doped into the silicon single crystal is controlled to be in a range of about 0.23 to about 0.45. Furthermore, some example embodiments of the inventive concepts may provide the method of manufacturing a silicon single crystal, wherein the initial concentration of oxygen is controlled to be within a range of about 1.5E17 atom/cm³ to about 4E17 atom/cm³ (about 3 ppma to about 8 ppma).

Some example embodiments of the inventive concepts may include a method of manufacturing a wafer, wherein the initial concentration of boron doped into a silicon single crystal is controlled to be within a range of about 8.0E12 atom/cm³ to about 1.5E13 atom/cm³. Additionally, some example embodiments of the inventive concepts may provide the method of manufacturing a wafer, wherein a doping concentration ratio, which is a ratio of an initial concentration of phosphorus to an initial concentration of boron doped into the silicon single crystal is controlled to be within a range of about 0.23 to about 0.45. Additionally, some example embodiments of the inventive concepts may provide the method of manufacturing a silicon single crystal, wherein the initial concentration of oxygen is controlled to be within a range of about 1.5E17 atom/cm³ to about 4E17 atom/cm³ (about 3 ppma to about 8 ppma).

Some example embodiments of the inventive concepts may include a method of manufacturing a silicon single crystal, the method including preparing a silicon melt, and growing the silicon single crystal based on co-doping boron and phosphorous into the silicon melt, wherein, in the growing of the silicon single crystal, the silicon single crystal is grown based on controlling a doping concentration ratio, which is a ratio of an initial concentration of phosphorus to an initial concentration of boron to be a particular (or, alternatively, predetermined) ratio, and controlling initial concentration of boron to be within a range of about 8.0E12 atom/cm³ to about 1.5E13 atom/cm³.

Additionally, some example embodiments of the inventive concepts may provide the method of manufacturing a silicon single crystal, the method including forming a silicon melt based on melting polycrystal silicon in a quartz crucible in a chamber, controlling resistivity distribution based on co-doping boron and phosphorus into the silicon melt, and growing the silicon single crystal based on rotating the quartz crucible, wherein, in the controlling of the resistivity distribution of the silicon single crystal, the resistivity distribution of the silicon single crystal is controlled based on controlling a doping concentration ratio, which is a ratio of an initial concentration of phosphorus to an initial concentration of boron to be a particular (or, alternatively, predetermined) ratio, and controlling the initial concentration of boron to be within a range of about 8.0E12 atom/cm³ to about 1.5E13 atom/cm³.

Additionally, some example embodiments of the inventive concepts may provide the method of manufacturing a wafer, the method including growing a silicon single crystal, slicing the silicon single crystal, lapping the silicon single crystal, and polishing the silicon single crystal, wherein, in the growing of the silicon single crystal, the silicon single crystal is grown based on controlling a doping concentration ratio, which is a ratio of an initial concentration of phosphorus to an initial concentration of boron, to be a particular (or, alternatively, predetermined) ratio, and controlling the initial concentration of boron to be within a range of about 8.0E12 atom/cm³ to about 1.5E13 atom/cm³.

### BRIEF DESCRIPTION OF THE DRAWINGS

Embodiments will be more clearly understood from the following detailed description taken in conjunction with the accompanying drawings in which:

FIG. 1 is a flowchart of a method of manufacturing a silicon single crystal, according to some example embodiments;

FIG. 2 is a graph illustrating resistivity of a silicon single crystal produced by a method of manufacturing a silicon single crystal, according to some example embodiments with respect to a doping concentration ratio and a position of the silicon single crystal;

FIG. 3 is a table showing first resistivity distribution and second resistivity distribution of a silicon single crystal produced by a method of manufacturing a silicon single crystal, according to some example embodiments, and a silicon single crystal produced according to a comparative embodiment;

FIG. 4 is a table showing a resistivity distribution changed due to an influence of thermal double donors (TDDs) for a silicon single crystal produced by a method of manufacturing a silicon single crystal, according to some example embodiments, and a silicon single crystal produced according to a comparative embodiment;

FIG. 5 is a table showing first resistivity distribution of a silicon single crystal produced by a method of manufacturing a silicon single crystal, according to some example embodiments;

FIG. 6 is a table showing second resistivity distribution of a silicon single crystal produced by a method of manufacturing a silicon single crystal, according to some example embodiments;

FIG. 7 is a table comparing first resistivity distribution of a silicon single crystal produced by a method of manufacturing a silicon single crystal, according to some example embodiments, with or without annealing;

FIG. 8 is a table comparing first resistivity distribution of a silicon single crystal produced by a method of manufacturing a silicon single crystal, according to some example embodiments, with or without annealing;

FIG. 9 is a flowchart of a method of manufacturing a wafer according to some example embodiments; and

FIG. 10 is a diagram schematically illustrating an electronic device according to some example embodiments.

### DETAILED DESCRIPTION

Hereinafter, some example embodiments of the inventive concepts are described in detail with reference to the accompanying drawings. Like drawing reference numerals are used for like elements, and duplicate descriptions thereof will be omitted.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

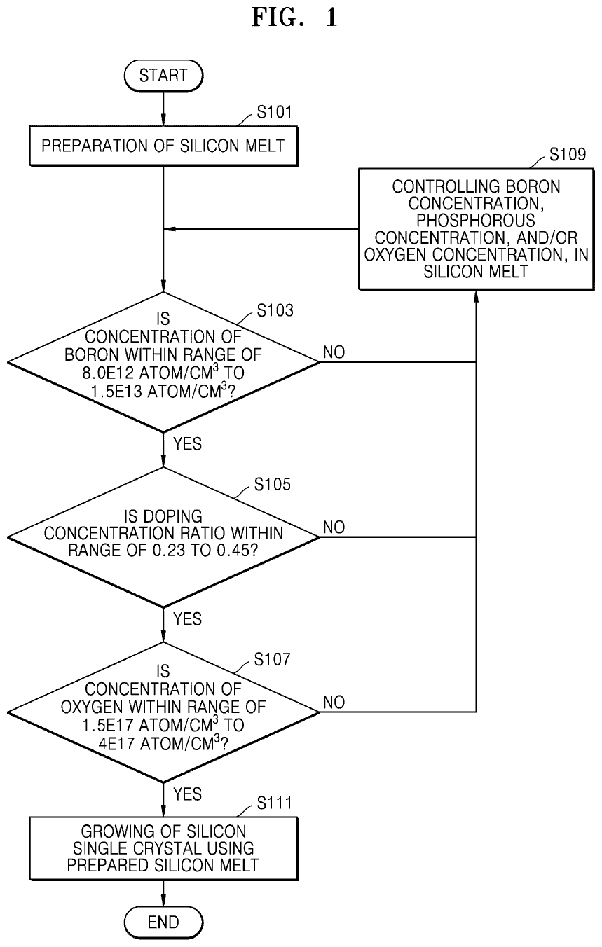

FIG. 1 is a flowchart of a method of manufacturing a silicon single crystal, according to some example embodiments of the inventive concepts.

Referring to FIG. 1, a method of manufacturing a silicon single crystal, according to some example embodiments, may include preparing a silicon melt (S101). In some example embodiments, the silicon melt is prepared by melting a polycrystal silicon, which may include polycrystalline silicon. For example, silicon raw material added with polycrystalline silicon and dopants as needed, are filled in a crucible made from quartz (e.g., a crucible comprising quartz, a crucible formed of quartz, etc.), and are melted in the crucible to prepare the silicon melt using a heater, etc.

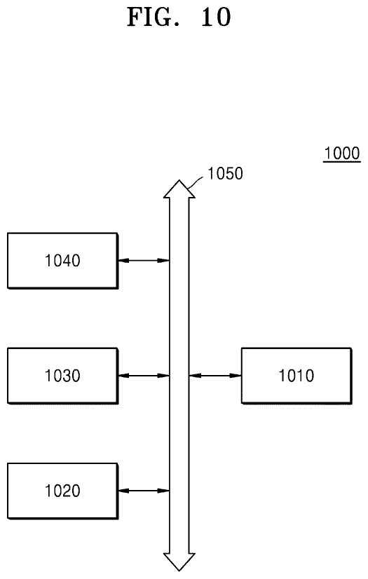

In some example embodiments, the preparation at S101 may include controlling a supply of materials into the crucible. For example, a device, such as the electronic device 1000 shown in FIG. 10, may control one or more gates, valves, pumps, actuators, or the like to control supply, flow, etc. of various materials into a crucible. The device may utilize one or more experimentally-generated look-up tables to determine an operation duration time and/or a particular control signal associated with operating one or more gates, valves, pumps, actuators, or the like coupled to a reservoir of one or more particular materials (e.g., silicon raw material, polycrystalline silicon, boron, phosphorous, oxygen, etc.) that corresponds to a particular (e.g., desired) amount of the material being supplied to the crucible as indicated by the look-up table, and the device may then operate the one or more gates, valves, pumps, actuators, or the like in accordance with the operation duration time and/or a particular control signal indicated by the one or more look-up tables to cause the particular amounts of the one or more particular materials to be supplied to the crucible, and to further activate and operate a heater to prepare the silicon melt (prior to, during, or subsequent to supplying one or more particular materials to the crucible), such that the silicon melt has particular initial concentrations of various dopants (e.g., boron, phosphorous, etc.). As described herein, an initial concentration of a material may refer to a concentration of the material in the silicon melt (e.g., prior to growth of a silicon single crystal using the silicon melt).

In some example embodiments, a device may be configured to cause the silicon melt to have particular dopant concentration characteristics, for example to cause a doping concentration ratio in the silicon melt, which is a ratio of an initial phosphorus concentration to an initial concentration of boron in the silicon melt, to be a particular ratio (e.g., within a range of about 0.23 to about 0.45) and for the initial concentration of boron in the silicon melt to be within a range of about 8.0E12 atom/cm³ to about 1.5E13 atom/cm³. In some example embodiments, the device may, at S101, 1) determine a desired (e.g., particular) silicon single crystal mass, 2) determine a corresponding amount of silicon raw material and/or polycrystalline silicon material corresponding to the desired silicon single crystal mass (e.g., 100%, 120%, 150%, 200%, etc. of the desired silicon single crystal mass), 3) determine particular amounts of boron (e.g., in the form of B2O3, pure boron, or any other boron-including material) and phosphorous (e.g., in the form of P2O5, pure phosphorus, or any other phosphorous-including material) to be added to the crucible to cause the silicon melt to have a doping concentration ratio, which is a ratio of an initial phosphorus concentration to an initial concentration of boron in the silicon melt, to be a particular ratio (e.g., within a range of about 0.23 to about 0.45) and for the initial concentration of boron in the silicon melt to be within a range of about 8.0E12 atom/cm³ to about 1.5E13 atom/cm³, 4) access one or more experimentally-generated look-up tables to determine operation durations and/or control signals to transmit to various gates, valves, actuators, pumps, or the like to cause the particular amounts of silicon raw material, polycrystalline silicon, boron, phosphorous, or any combination thereof to be supplied into the crucible. In some example embodiments, the silicon melt may be prepared based on the device controlling a heater (e.g., an electrically resistive heater) to melt silicon raw material and/or polycrystalline silicon in the crucible, and boron and phosphorous may be co-doped into the silicon melt during or subsequent to the melting of the silicon raw material and/or polycrystalline silicon in the crucible, to control the “initial” concentration of boron and phosphorous in the silicon melt. In some example embodiments, the boron and phosphorous may be supplied to the crucible prior to activating the heater.

The silicon single crystal may be grown by using the Czochralski method (also referred to herein as a Czochralski method process, a Czochralski process, or the like. (S111). It will be understood that the growing of a silicon single crystal as described herein may be referred to as growing a silicon single crystal from a silicon melt according to any of the example embodiments. For example, in some example embodiments of the growing at S111, a seed is connected to the silicon melt, and a crucible containing the seed and the silicon melt is rotated (e.g., the crucible may be rotated in relation to the seed, the seed may be rotated in relation to the crucible, or any combination thereof) to grow a silicon single crystal. In some example embodiments, the silicon single crystal may be a p-type silicon single crystal. In growing of the silicon single crystal, boron and phosphorus may be co-doped into the silicon melt, for example based on a device (e.g., electronic device 1000) controlling one or more gates, valves, pumps, actuators, or the like that are coupled to boron and/or phosphorous material reservoirs to control the supply, flow, or the like of boron and/or phosphorous materials into the crucible containing the silicon melt. The co-doped boron may be supplied to the silicon melt in the form of any boron-containing material in any phase (solid, liquid, gas, or any combination thereof), including for example B2O3, pure boron material, or the like. The co-doped phosphorous may be supplied to the silicon melt in the form of any phosphorous-containing material in any phase (solid, liquid, gas, or any combination thereof), including for example P2O5, pure phosphorus material, or the like. Co-doped materials may be supplied to the silicon melt simultaneously, sequentially, or any combination thereof. A silicon single crystal grown according to the inventive concepts may be a p-type silicon single crystal having a resistivity of 1000 Ω·cm or more (e.g., a resistivity of about 1000 Ω·cm to about 10000 Ω·cm).

In the growing of a silicon single crystal of a method for manufacturing a silicon single crystal, according to some example embodiments, an initial concentration of boron (also referred to herein interchangeably as the initial concentration of boron in the silicon melt) may be controlled to be a particular (or, alternatively, predetermined) concentration (S103). In some example embodiments, the particular (or, alternatively, predetermined) initial concentration of boron may be controlled to be, for example, within a range of about 8.0E12 atom/cm³ (e.g., 8.0×10¹² atom/cm³) to about 1.5E13 atom/cm³ (e.g., 1.5×10¹³ atom/cm³).

Additionally, in the growing of a silicon single crystal, a doping concentration ratio, which is a ratio of the initial concentration of phosphorus (also referred to herein interchangeably as the initial concentration of phosphorous in the silicon melt) to the initial concentration of boron, may be controlled to be a particular (or, alternatively, predetermined) ratio (S105). In the growing, the doping concentration ratio may be controlled to be within a range of about 0.23 to about 0.45. In some example embodiments, the doping concentration ratio may be controlled to be within a range of about 0.35 to about 0.45.

When the initial concentration of boron is controlled to be within a range of about 8.0E12 atom/cm³ to about 1.5E13 atom/cm³, the initial concentration of phosphorus may be controlled to be within a range of about 1.840E12 atom/m3 to about 6.75E12 atom/cm³. For example, the initial concentration of phosphorus may be controlled to be within a range of about 2E12 atom/cm³ to about 6.75E12 atom/cm³.

In the case of a comparative embodiment, in which solely boron (e.g., boron and not any phosphorous) is doped into the silicon melt to grow a p-type silicon single crystal, there is a limitation in which it is difficult to control the resistivity distribution of the silicon single crystal due to the segregation coefficient of boron.

According to a comparative embodiment, in the section of 0 to 0.9 of the silicon single crystal, first resistivity distribution of the silicon single crystal may exceed 30%. There is a limitation in which the uniformity of the silicon single crystal is lowered as the first resistivity distribution of the silicon single crystal increases. Herein, the section of 0 to 0.9 of the silicon single crystal means, when the silicon single crystal is grown, a section from one end (0) that is not connected with the seed to the 90% position (0.9) of the silicon single crystal. Additionally, the first resistivity distribution may be calculated by Equation 1 below.

$$First resistivity distribution = \frac{range values of resistivity}{median value of resistivity} \times 100 \qquad [ Equation 1 ]$$

The range value of resistivity means a difference between the resistivity values at both ends of the corresponding section (for example, 0 to 0.9), and the median value of resistivity means a resistivity value corresponding to the middle among the resistivity values in the corresponding section (for example, 0 to 0.9).

The effect that the resistivity distribution of the silicon single crystal may be improved by controlling the concentration of boron and the doping concentration ratio between boron and phosphorus, may be achieved. Unlike the comparative embodiments, the method of manufacturing a silicon single crystal, according to some example embodiments, has the effect that may control the first resistivity distribution of the silicon single crystal to be within 20%. In other words, the inventive concepts have the effect of reducing the resistivity distribution of the silicon single crystal.

The growing of the silicon single crystal may further include controlling a concentration of oxygen injected into the silicon melt (e.g., based on a device such as electronic device 1000 controlling a valve coupled to an oxygen reservoir containing liquid oxygen to cause oxygen to be directed through a nozzle into the crucible to be injected into the silicon melt). In some example embodiments, oxygen may be injected into the silicon melt with (e.g., at least partially simultaneously with) co-doping of boron and phosphorus. The initial concentration of oxygen (also referred to herein interchangeably as the initial concentration of oxygen in the silicon melt, the initial concentration of oxygen injected into the silicon melt, the concentration of oxygen injected into the silicon melt, the concentration of oxygen in the silicon melt, or the like) may be controlled to be a particular (or, alternatively, predetermined) concentration (S107). In some example embodiments, the initial concentration of oxygen may be controlled to be within a range of about 1.5E17 atom/cm³ to about 4E17 atom/cm³ (about 3 ppma to about 8 ppma).

By controlling the initial concentration of oxygen to be within a range of about 1.5E17 atom/cm³ to about 4E17 atom/cm³, the effects including suppressing (e.g., reducing, minimizing, or preventing) the increase of the resistivity distribution of the silicon single crystal may be achieved after performing the subsequent process such as far back end of line (FBEOL). For example, in the subsequent process of manufacturing a wafer by slicing the silicon single crystal and processing the wafer, thermal double donors (TDDS) may be formed. TDDS have a limitation in which the wafer may deteriorate, and thus, the resistivity distribution between wafers may increase.

In some example embodiments, a method of manufacturing a silicon single crystal, according to some example embodiments, has the effects that the resistivity distribution of the silicon single crystal may be controlled by controlling the initial concentration of boron and the doping concentration ratio between boron and phosphorus, and resistivity distribution between wafers may be improved (e.g., increase in resistivity distribution may be suppressed), and thus uniformity of the wafers may be improved, thereby improving the performance and/or reliability of semiconductor devices and/or electronic devices including at least a portion of such wafers, by controlling the initial concentration of oxygen.

By the method of manufacturing a silicon single crystal, according to some example embodiments, a p-type silicon single crystal may be grown by controlling the initial concentration of boron to be within a range of about 8.0E12 atom/cm³ to about 1.5E13 atom/cm³, controlling the doping concentration ratio to be within about 0.23 to about 0.45, and controlling the initial concentration of oxygen to be within a range of about 1.5E17 atom/cm³ to about 4E17 atom/cm³ (about 3 ppma to about 8 ppma).

Still referring to FIG. 1, the operations at S103, S105, and S107 may be performed to control the co-doping of boron and phosphorous and/or the injection of oxygen into the silicon melt at S109, to cause the initial boron concentration in the silicon melt to be with the range of about 8.0E12 atom/cm³ to about 1.5E13 atom/cm³ (S103=YES), to cause the doping concentration ratio in the silicon melt to be within about 0.23 to about 0.45 (S105=YES), and the initial concentration of oxygen in the silicon melt to be within a range of about 1.5E17 atom/cm³ to about 4E17 atom/cm³ (about 3 ppma to about 8 ppma) (S107=YES). In response to a determination that S103/S105/S107=YES, the growing of the silicon single crystal using the silicon melt (also referred to herein as growing the silicon single crystal from the silicon melt and/or based on the silicon melt) may proceed at S111 (e.g., based on a device such as electronic device 1000 controlling an actuator to cause a seed to be connected to the silicon melt and further controlling one or more actuators, motors, servo actuators, or the like to cause rotation of at least one of the seed or the crucible while withdrawing the seed from the silicon melt to cause the silicon single crystal to be grown.

Still referring to FIG. 1, the operations at S103, S105, S107, and S109 may be performed based on a device (e.g., electronic device 1000) performing one or more operations which may include 1) determining a mass of the silicon melt prepared at S101, for example based on determining an amount of silicon raw material and/or polycrystalline silicon added to the crucible to prepare the silicon melt at S101, 2) determining particular amounts of boron (e.g., in the form of B2O3, pure boron, or any other boron-including material), phosphorous (e.g., in the form of P2O5, pure phosphorus, or any other phosphorous-including material), and oxygen (e.g., in the form of injected liquid oxygen, gaseous oxygen, or the like) to be added to the crucible to cause the initial concentration of boron in the silicon melt to be within a range of about 8.0E12 atom/cm³ to about 1.5E13 atom/cm³ (S103=YES), to cause the doping concentration ratio in the silicon melt to be within a range of about 0.23 to about 0.45 (S105=YES) and to cause the initial concentration of oxygen in the silicon melt to be within a range of about 1.5E17 atom/cm³ to about 4E17 atom/cm³ (S107=YES), 3) access one or more experimentally-generated look-up tables to determine operation durations and/or control signals to transmit to various gates, valves, actuators, pumps, or the like to cause the particular amounts of boron, phosphorous, oxygen, or any combination thereof to be supplied into the crucible, and 4) operating the various gates, valves, actuators, pumps in accordance with the look-up table data to control the supply of boron, phosphorous, and oxygen into the silicon melt at S109. Based on such an operation at S109, the device may conclude that S103 to S107 are each met (e.g., each of S103, S105, S107 is determined to be “yes”), such that the device may, in response to performing S109, proceed to performing silicon single crystal growth at S111.

In some example embodiments, where the boron-containing material and/or the phosphorous-containing material supplied to the crucible further contain oxygen (e.g., in example embodiments where the co-doped boron and phosphorous are supplied in the form of B2O3 and P2O5, respectively), the determining of the amount of oxygen to be added (e.g., supplied, injected, etc.) into the silicon melt may include accounting for the oxygen provided to the crucible via the supplying of the boron-containing material and/or the phosphorous-containing material into the crucible, thereby avoiding excess supplying of oxygen into the silicon melt. Such accounting may be provided by a look-up table which associates particular operating durations and/or control signals to control oxygen injection into the silicon melt with particular combinations of respective amounts and/or concentrations of particular boron-containing materials, phosphorous-containing materials, silicon materials, any combination thereof, or the like in the silicon melt.

While operation S109 is shown in FIG. 1 to be performed on the silicon melt prior to the preparation thereof at S101, it will be understood that one or more of boron, phosphorous, or oxygen supply into the crucible may be performed prior to or as part of the preparation of the silicon melt at S101. For example, operation S109 may include supplying the boron and phosphorous into the crucible prior to the heater being activated to melt the materials therein to form the silicon melt at S101 (e.g., prior to S101 being completed), and operation S109 may include injecting the oxygen into the silicon melt subsequent to S101 being completed. In another example, operation S109 may include supplying the boron, phosphorous, and oxygen into the silicon melt subsequently to S101 being completed. In some example embodiments the boron and phosphorous may be added to the crucible prior to activating the heater.

It will be understood that, in some example embodiments, the operation at S107 may be omitted and oxygen injection into the silicon melt may be omitted from the method shown in FIG. 1.

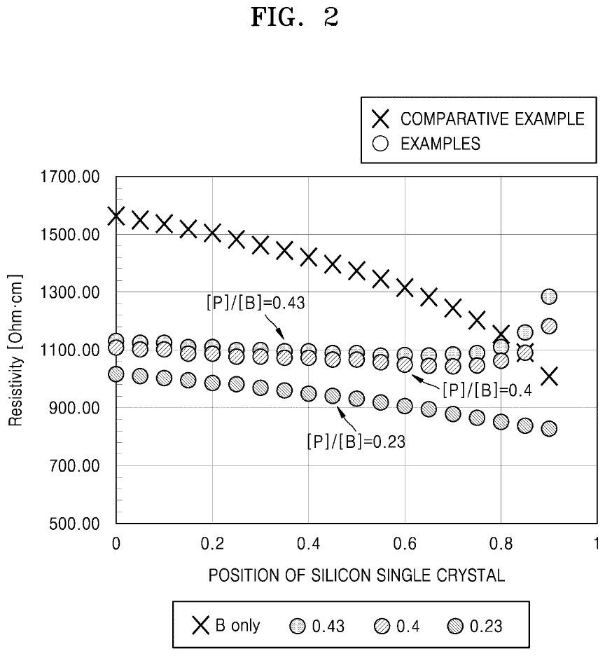

FIG. 2 is a graph illustrating a resistivity of a silicon single crystal produced by a method of manufacturing a silicon single crystal, according to some example embodiments, with respect to a doping concentration ratio and a position of the silicon single crystal.

Referring to FIG. 2, when the silicon single crystal is produced by a manufacturing method according to a comparative embodiment, it can be seen that the resistivity decreases as a position of the silicon single crystal increases. For example, it can be seen that the resistivity of the silicon single crystal at one end (0) is about 1550 Ω·cm, whereas the resistivity of the silicon single crystal tends to decrease as the position of the silicon single crystal moves to the other end (1). At this time, the initial concentration of boron may be about 1.05E13 atom/cm³.

In some example embodiments, it can be seen that, when a silicon single crystal is produced by a manufacturing method according to some example embodiments, the resistivity of the silicon single crystal is relatively uniform compared to that of a silicon single crystal according to a comparative embodiment. Such uniformity may result in improved operational performance and/or reliability of semiconductor devices and/or electronic devices including at least a portion of wafers manufactured from the silicon single crystal.

It can be seen that, when a doping concentration ratio, which is a ratio of an initial concentration of phosphorus to an initial concentration of boron, is 0.4 or 0.43, as the position of the silicon single crystal moves from one end (0) to the other end (1), the resistivity of the silicon single crystal tends to decrease. Additionally, it can be seen that, when the silicon single crystal is produced by a manufacturing method according to the inventive concepts, the resistivity value of the silicon single crystal is uniformly distributed in the section of 0 to 0.8 of the silicon single crystal, compared to a comparative embodiment doped solely with boron (e.g., doped with boron and not doped with any phosphorous).

Furthermore, it can be seen that, when the doping concentration ratio, which is a ratio of the initial phosphorus concentration (also referred to herein interchangeably as the initial concentration of phosphorous) to the initial concentration of boron, is 0.23, as the position of the silicon single crystal moves from one end (0) to the other end (1), the resistivity of the silicon single crystal tends to decrease. Additionally, it can be seen that, when the silicon single crystal is produced by a manufacturing method according to the inventive concepts, the resistivity value of the silicon single crystal is uniformly distributed in the section of 0 to 0.8 of the silicon single crystal, compared to a comparative embodiment doped solely with boron.

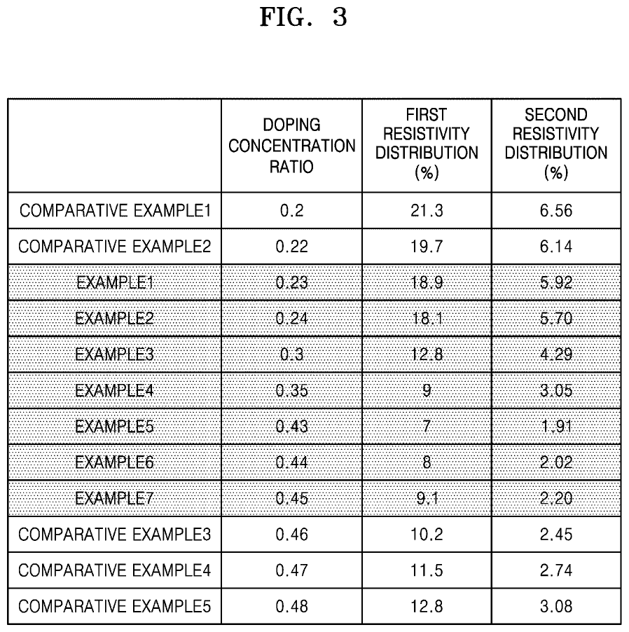

FIG. 3 is a table showing first resistivity distribution and second resistivity distribution of the silicon single crystal produced by a method of manufacturing a silicon single crystal, according to some example embodiments, and a silicon single crystal produced according to a comparative embodiment.

Referring to FIG. 3, it can be seen that, with respect to an initial doping concentration ratio of boron and phosphorus co-doped in the growing process of the silicon single crystal, the first resistivity distribution value and the second resistivity distribution value change. The table in FIG. 3 shows calculated results of the first resistivity distribution and the second resistivity distribution using resistivity value in the section of 0 to 0.85 of the silicon single crystal. The first resistivity distribution and the second resistivity distribution may be calculated using Equations 1 and 2 below, respectively.

$$\begin{matrix}First resistivity distribution = \frac{range values of resistivity}{median value of resistivity} \times 100 & [ Equation 1 ] \\ Second resistivity distribution = \frac{standard deviation}{median value of resistivity} \times 100 & [ Equation 2 ]\end{matrix}$$

As described above, a range value of the resistivity means a difference between the resistivity values at both ends of the corresponding section (for example, 0 to 0.85), and a median value of the resistivity means a resistivity value corresponding to the middle among resistivity values in the corresponding section (for example, 0 to 0.8). Additionally, a standard deviation of resistivity means a standard deviation value of resistivity values in the corresponding section (for example, 0 to 0.85).

Referring to Comparative Example 1, it can be seen that, when the doping concentration ratio is 0.2, the first resistivity distribution of the silicon single crystal is 21.3%. It can be seen that, when the doping concentration ratio is 0.2, the second resistivity distribution is 6.56%.

Referring to Comparative Example 2, it can be seen that, when the doping concentration ratio is 0.22, the first resistivity distribution of the silicon single crystal is 19.7%. It can be seen that, when the doping concentration ratio is 0.22, the second resistivity distribution of the silicon single crystal is 6.14%.

Referring to Example 1, it can be seen that, when the doping concentration ratio is 0.23, the first resistivity distribution of the silicon single crystal is 18.9%. It can be seen that, when the doping concentration ratio is 0.23, the second resistivity distribution of the silicon single crystal is 5.92%.

Referring to Example 2, it can be seen that, when the doping concentration ratio is 0.24, the first resistivity distribution of the silicon single crystal is 18.1%. It can be seen that, when the doping concentration ratio is 0.24, the second resistivity distribution of the silicon single crystal is 5.70%.

Referring to Example 3, it can be seen that, when the doping concentration ratio is 0.3, the first resistivity distribution of the silicon single crystal is 12.8%. It can be seen that, when the doping concentration ratio is 0.3, the second resistivity distribution of the silicon single crystal is 4.29%.

Referring to Example 4, it can be seen that, when the doping concentration ratio is 0.35, the first resistivity distribution of the silicon single crystal is 9%. It can be seen that, when the doping concentration ratio is 0.35, the second resistivity distribution of the silicon single crystal is 3.05%.

Referring to Example 5, it can be seen that, when the doping concentration ratio is 0.43, the first resistivity distribution of the silicon single crystal is 7%. It can be seen that, when the doping concentration ratio is 0.43, the second resistivity distribution of the silicon single crystal is 1.91%.

Referring to Example 6, it can be seen that, when the doping concentration ratio is 0.44, the first resistivity distribution of the silicon single crystal is 8%. It can be seen that, when the doping concentration ratio is 0.44, the second resistivity distribution of the silicon single crystal is 2.02%.

Referring to Example 7, it can be seen that, when the doping concentration ratio is 0.45, the first resistivity distribution of the silicon single crystal is 9.1%. It can be seen that, when the doping concentration ratio is 0.45, the second resistivity distribution of the silicon single crystal is 2.20%.

In the case of Comparative Example 1, the first resistivity distribution of the silicon single crystal exceeds 20%, and the second resistivity of the silicon single crystal exceeds 6%. In the case of Comparative Example 2, the second resistivity distribution of the silicon single crystal exceeds 6%. In comparison, according to Examples 1 to 7, the first resistivity distribution of the silicon single crystal may be controlled to be less than 20%, and the second resistivity distribution of the silicon single crystal may be controlled to be less than 6%. In other words, some example embodiments (e.g., Examples 1 to 7) secure the uniformity of the resistivity of the silicon single crystal (e.g., the first resistivity distribution being less than 20% combined with the second resistivity distribution being less than 6%) compared to comparative embodiments (e.g., Comparative Examples 1 to 5). Such uniformity may result in improved operational performance and/or reliability of semiconductor devices and/or electronic devices including at least a portion of wafers manufactured from the silicon single crystal.

In other words, by a method of manufacturing a silicon single crystal of the inventive concepts, in the growing of the silicon single crystal, the doping concentration ratio, which is the ratio of the initial concentration of phosphorus to the initial concentration of boron, may be controlled to be within a range of about 0.23 to about 0.45. By controlling the doping concentration ratio to be within a range of about 0.23 to about 0.45, effects that may decrease the resistivity distribution of the silicon single crystal, may be achieved. Such decreased resistivity distribution may result in improved operational performance and/or reliability of semiconductor devices and/or electronic devices including at least a portion of wafers manufactured from the silicon single crystal.

Particularly, when the doping concentration ratio is controlled to be within a range of about 0.35 to about 0.45 (for example, Examples 4 to 7), an effect that the first resistivity distribution of the silicon single crystal may be controlled to be within 10%, and the second resistivity distribution of the silicon single crystal may be controlled to be within 3.1%, may be achieved.

Referring to Comparative Example 3, it can be seen that, when the doping concentration ratio is 0.46, the first resistivity distribution of the silicon single crystal is 10.2%. It can be seen that, when the doping concentration ratio is 0.46, the second resistivity distribution is 2.45%.

Referring to Comparative Example 4, it can be seen that, when the doping concentration ratio is 0.47, the first resistivity distribution of the silicon single crystal is 11.5%. It can be seen that, when the doping concentration ratio is 0.47, the second resistivity distribution of the silicon single crystal is 2.74%.

Referring to Comparative Example 5, it can be seen that, when the doping concentration ratio is 0.48, the first resistivity distribution of the silicon single crystal is 12.8%. It can be seen that, when the doping concentration ratio is 0.48, the second resistivity distribution of the silicon single crystal is 3.08%.

In the cases of Comparative Examples 3 to 5, the first resistivity distribution of the silicon single crystal may be controlled to be less than 20%, and the second resistivity distribution of the silicon single crystal may be controlled to be less than 6%. However, as in Comparative Examples 3 to 5 when having the increased doping concentration ratio (for example, the doping concentration ratio is at least 0.46), the resistivity distribution of a wafer may be degraded due to the formation of thermal double donors (TDDs) formed in the subsequent process of processing the wafer. As a result, based on controlling the doping concentration ratio to be equal to or less than 0.45 (e.g., about 0.23 to about 0.45) the resistivity distribution may be caused to be relatively uniform while also reducing, minimizing, or preventing the risk of degraded resistivity distribution of a wafer may be degraded due to the formation of thermal double donors (TDDs) formed in the subsequent process of processing the wafer. Such uniformity may result in improved operational performance and/or reliability of semiconductor devices and/or electronic devices including at least a portion of wafers manufactured from the silicon single crystal.

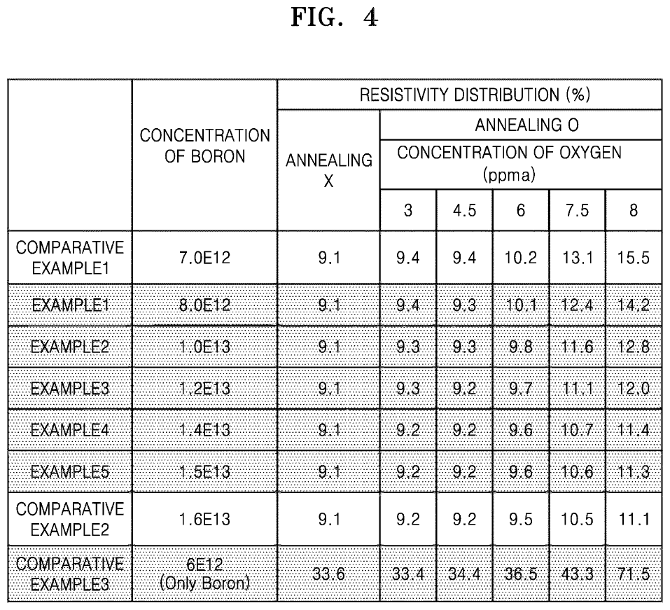

FIG. 4 is a table showing resistivity distribution changed due to an influence of thermal double donors (TDDs) in a silicon single crystal produced by a method of manufacturing a silicon single crystal, according to some example embodiments, and a silicon single crystal produced according to a comparative embodiment.

Referring to FIG. 4, it can be seen that, in the growing of the silicon single crystal according to some example embodiments or the comparative embodiment, the resistivity distribution changes with respect to an initial concentration of oxygen. Herein, the resistivity distribution is first resistivity distribution according to Equation 1 described above. Additionally, the resistivity distribution is first resistivity distribution of which doping concentration ratio is controlled to be 0.45, except for Comparative Example 3. However, the first resistivity distribution is first resistivity distribution between wafers produced by slicing the silicon single crystal.

Referring to Comparative Examples 1 and 2 and Examples 1 to 5, it can be seen that, when the wafer is not annealed in the subsequent process, the first resistivity distribution between wafers is 9.1%.

When an annealing is performed in the subsequent process of the wafer, thermal double donors may be formed. Due to the thermal double donors, the resistivity distribution between wafers may be degraded. To improve (e.g., reduce, minimize, or prevent) the degradation of the resistivity distribution, in a method of manufacturing a silicon single crystal, according to some example embodiments, an initial concentration of oxygen (e.g., initial concentration of oxygen in the silicon melt, initial concentration of oxygen injected into the silicon melt, etc.) may be controlled in the growing of the silicon single crystal. In some example embodiments, the initial concentration of oxygen may be controlled to be within a range of about 1.5E17 atom/cm³ to about 4E17 atom/cm³ (about 3 ppma to about 8 ppma).

For example, the subsequent process such as a Far-BEOL process may be performed for a 2.5 D interposer using a wafer having a high resistivity of 1000 Ω·cm or more, etc. In the processing of the subsequent process, there may not be a temperature window in which the thermal double donors may be annihilated. Therefore, the controlling of the initial concentration of oxygen as disclosed herein may result in improved operational performance and/or reliability of semiconductor devices and/or electronic devices including at least a portion of wafers manufactured from the silicon single crystal, based on improving (e.g., reducing, minimizing, or preventing) degradation of the resistivity distribution of wafers in subsequent processes (e.g., annealing processes) due to thermal double donors.

In Comparative Example 3, the silicon single crystal is grown by using solely boron, for example without co-doping the boron with any phosphorous (where, the initial concentration of boron is 6E12 atom/cm³). In Comparative Example 3, when the wafer is not annealed, the first resistivity distribution of the silicon single crystal is 33.6%. In some example embodiments, in Comparative Example 3, when the annealing is performed, it can be seen that, the first resistivity distribution of the silicon single crystal increases significantly, even though the initial concentration of oxygen is controlled. For example, it can be seen that, when the initial concentration of oxygen is 8 ppma, the first resistivity distribution of the silicon single crystal increases up to 71.5%.

In Comparative Examples 1 and 2, the initial concentration of boron is out of the range of about 8.0E12 atom/cm³ to about 1.5E13 atom/cm³. To produce the silicon single crystal having a high resistivity of 1000 Ω·cm or more, the initial concentration of boron may be controlled to be within a range of about 8.0E12 atom/cm³ to about 1.5E13 atom/cm³.

According to Examples 1 to 5, when the initial concentration of boron is controlled to be within a range of about 8.0E12 atom/cm³ to about 1.5E13 atom/cm³, and the initial concentration of oxygen is controlled to be within a range of about 1.5E17 atom/cm³ to about 4E17 atom/cm³ (about 3 ppma to about 8 ppma), effects that the first resistivity distribution between wafers may be controlled to be within 15%, may be achieved. Such control in the first resistivity distribution may result in improved operational performance and/or reliability of semiconductor devices and/or electronic devices including at least a portion of wafers manufactured from the silicon single crystal.

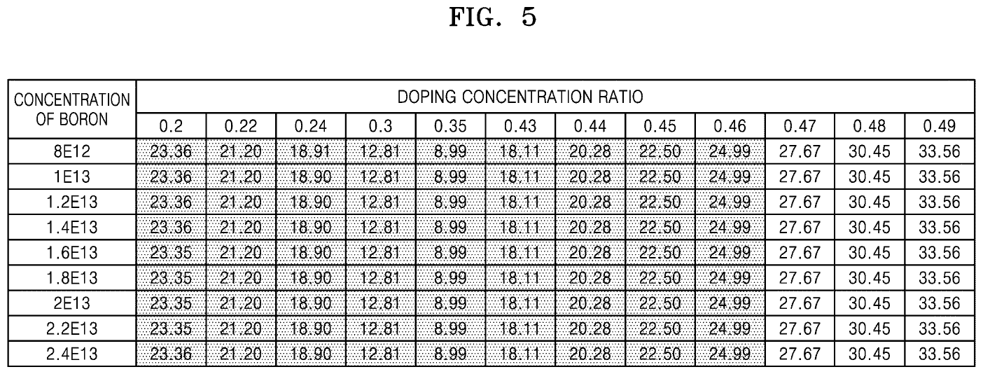

FIG. 5 is a table showing first resistivity distribution of a silicon single crystal produced by a method of manufacturing a silicon single crystal, according to some example embodiments.

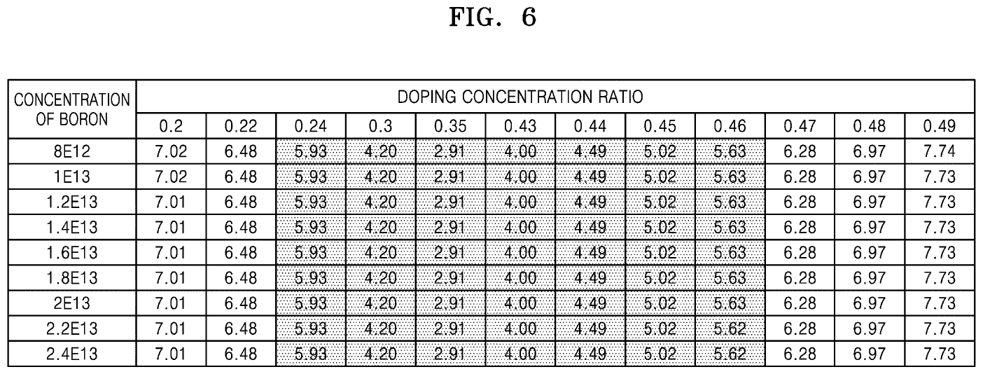

FIG. 6 is a table showing second resistivity distribution of a silicon single crystal produced by a method of manufacturing a silicon single crystal, according to some example embodiments.

FIGS. 5 and 6 respectively illustrate first resistivity distribution and second resistivity distribution in the section of 0 to 0.9 of the silicon single crystal with respect to a doping concentration ratio. The first resistivity distribution may be calculated by Equation 1 described above, and the second resistivity distribution may by calculated by Equation 2 described above. In some example embodiments, the initial concentration of boron may be controlled to be within a range of about 8.0E12 atom/cm³ to about 2.4E13 atom/cm³.

Referring to FIG. 5, in the section of 0 to 0.9 of the silicon single crystal, the first resistivity distribution is controlled not to exceed 25%. At this time, a doping concentration ratio, which is a ratio of an initial concentration of phosphorus to an initial concentration of boron, is controlled to be within a range of about 0.2 to about 0.46.

Referring to FIG. 6, in the section of 0 to 0.9 of the silicon single crystal, the second resistivity distribution is controlled not to exceed 6%. In some example embodiments, the doping concentration ratio is controlled to be within a range of about 0.24 to about 0.46.

According to some example embodiments, an effect that first resistivity distribution and second resistivity distribution of the silicon single crystal are controlled by controlling the initial concentration of boron to be within a range of about 8.0E12 atom/cm³ to about 2.4E13 atom/cm³ and controlling a doping concentration ratio to be within a range of about 0.24 to about 0.46, may be achieved. Such control may result in improved operational performance and/or reliability of semiconductor devices and/or electronic devices including at least a portion of wafers manufactured from the silicon single crystal.

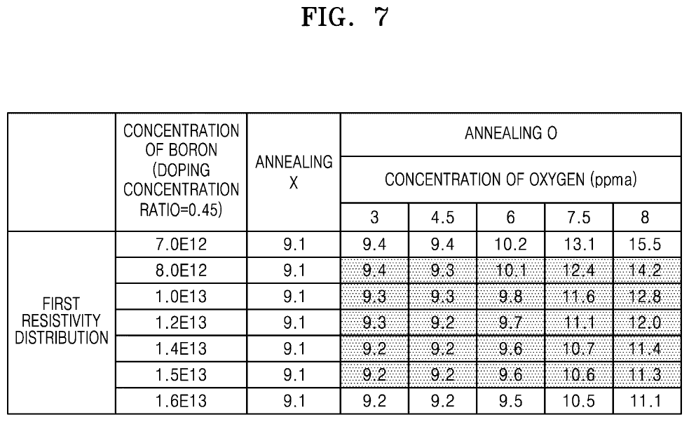

FIG. 7 is a table comparing first resistivity distribution of a silicon single crystal produced by a method of manufacturing a silicon single crystal, according to some example embodiments, with or without annealing.

Referring to FIG. 7, it can be seen that resistivity distribution changes with respect to the initial concentration of oxygen in the growing of the silicon single crystal according to some example embodiments or comparative embodiment. In some example embodiments, the resistivity distribution is the first resistivity distribution according to Equation 1 described above. FIG. 7 illustrates first resistivity distribution when the doping concentration ratio is controlled to be 0.45. For example, the resistivity distribution in FIG. 7 is the first resistivity distribution calculated by using a resistivity value in the section of 0 to 0.85 of the silicon single crystal.

It can be seen that, when an annealing is not performed in the subsequent process, the first resistivity distribution of the silicon single crystal is 9.1%. When the annealing is performed in the subsequent process, thermal double donors may be formed. Due to the thermal double donors, the resistivity distribution of the silicon single crystal may be degraded. To improve (e.g., reduce, minimize, or prevent) the degradation of the resistivity distribution, by a method of manufacturing a silicon single crystal, according to some example embodiments, the initial concentration of oxygen may be controlled in the growing of the silicon single crystal. For example, the initial concentration of oxygen may be controlled to be within a range of about 1.5E17 atom/cm³ to about 4E17 atom/cm³ (about 3 ppma to about 8 ppma). Such control may result in improved operational performance and/or reliability of semiconductor devices and/or electronic devices including at least a portion of wafers manufactured from the silicon single crystal, for example based on reducing degradation of the resistivity distribution of the wafers due to thermal double donors in subsequent manufacturing operations.

Referring to FIG. 7, when the initial concentration of boron is controlled to be within a range of about 8.0E12 atom/cm³ to about 1.5E13 atom/cm³, the doping concentration ratio is controlled to be 0.45, and the initial concentration of oxygen is controlled to be within a range of about 1.5E17 atom/cm³ to about 4E17 atom/cm³ (about 3 ppma to about 8 ppma), an effect that first resistivity distribution of the silicon single crystal may be controlled to be within 15%, may be achieved even when an annealing is performed in the subsequent process. Such control may result in improved operational performance and/or reliability of semiconductor devices and/or electronic devices including at least a portion of wafers manufactured from the silicon single crystal, for example based on reducing degradation of the resistivity distribution of the wafers due to thermal double donors in subsequent manufacturing operations.

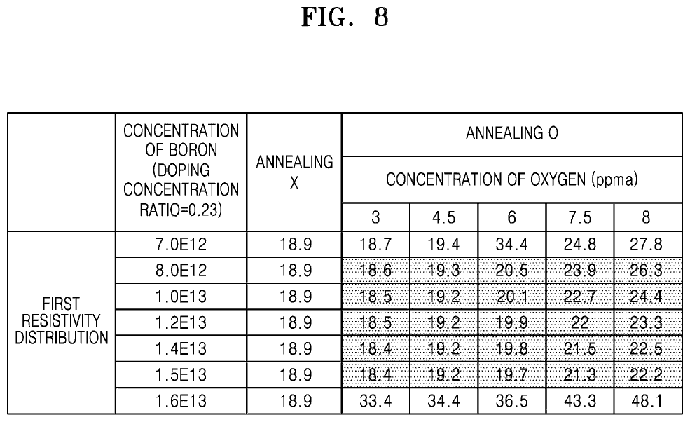

FIG. 8 is a table comparing first resistivity distribution of a silicon single crystal produced by a method of manufacturing a silicon single crystal, according to some example embodiments, with or without annealing.

Referring to FIG. 8, it can be seen that the resistivity distribution changes with respect to the initial concentration of oxygen in the growing of the silicon single crystal according to some example embodiments or a comparative embodiment. In some example embodiments, the resistivity distribution is first resistivity distribution according to Equation 1 described above. The resistivity distribution in FIG. 8 is first resistivity distribution when the doping concentration ratio is controlled to be 0.23. For example, the resistivity distribution in FIG. 8 is the first resistivity distribution calculated using a resistivity value in the section of 0 to 0.85 of a silicon single crystal.

It can be seen that, when the annealing is not performed in the subsequent process, the first resistivity distribution of the silicon single crystal is 18.9%. When the annealing is performed in the subsequent process, thermal double donors may be formed. Due to the thermal double donors, the resistivity distribution of the silicon single crystal may be degraded. To improve the degradation of the resistivity distribution, by a method of manufacturing a silicon single crystal, according to some example embodiments, the initial concentration of oxygen may be controlled in the growing of the silicon single crystal. For example, the initial concentration of oxygen may be controlled to be within a range of about 1.5E17 atom/cm³ to about 4E17 atom/cm³ (about 3 ppma to about 8 ppma). Such control may result in improved operational performance and/or reliability of semiconductor devices and/or electronic devices including at least a portion of wafers manufactured from the silicon single crystal, for example based on reducing degradation of the resistivity distribution of the wafers due to thermal double donors in subsequent manufacturing operations.

Referring to FIG. 8, when the initial concentration of boron is controlled to be within a range of about 8.0E12 atom/cm³ to about 1.5E13 atom/cm³, the doping concentration ratio is controlled to be 0.23, and the initial concentration of oxygen is controlled to be within a range of about 1.5E17 atom/cm³ to about 4E17 atom/cm³ (about 3 ppma to about 8 ppma), even though the annealing is performed in the subsequent process, an effect that the first resistivity distribution may be controlled to be within 27%, is achieved. Such control may result in improved operational performance and/or reliability of semiconductor devices and/or electronic devices including at least a portion of wafers manufactured from the silicon single crystal, for example based on reducing degradation of the resistivity distribution of the wafers due to thermal double donors in subsequent manufacturing operations.

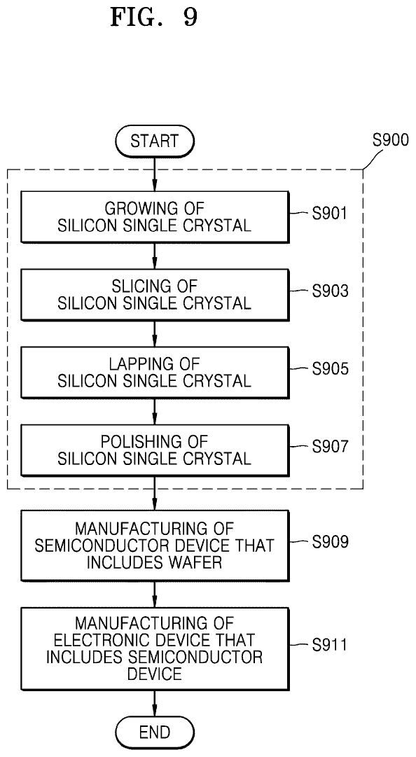

FIG. 9 is a flowchart of a method that includes a method of manufacturing a wafer, according to some example embodiments.

Referring to FIG. 9, the method of manufacturing a wafer (S900), according to some example embodiments, may include growing a silicon single crystal (S901). The growing at S901 may include performing some or all of the operations of the method shown in FIG. 1, such that the growing at S901 may be understood to include growing a silicon single crystal from a silicon melt, which may be silicon melt prepared according to any of the example embodiments. A silicon melt may be prepared, and the silicon single crystal may be grown by the Czochralski method. For example, a seed is connected to the silicon melt, and the silicon single crystal may be grown by rotating a crucible containing the seed and the silicon melt. In some example embodiments, the silicon single crystal may be a p-type silicon single crystal. In the growing of the silicon single crystal, boron and phosphorus may be co-doped into the silicon melt as described above with reference to the method shown in FIG. 1. In the growing of the silicon single crystal, oxygen may be injected into the silicon melt as described above with reference to the method shown in FIG. 1. In some example embodiments, the growing at S901 may correspond to the growing at S111 shown in FIG. 1, where the growing is based on S101 to S109 or any combination thereof as shown in FIG. 1. In some example embodiments, the silicon single crystal may be grown in a cylinder shape.

In the growing of the silicon single crystal, the initial concentration of boron may be controlled to be a particular (or, alternatively, predetermined) concentration. For example, the initial concentration of boron may be controlled to be within a range of about 8.0E12 atom/cm³ to about 1.5E13 atom/cm³.

Additionally, in the growing of the silicon single crystal, the doping concentration ratio, which is a ratio of the initial concentration of phosphorus to the initial concentration of boron, may be controlled to be a particular (or, alternatively, predetermined) ratio. For example, the doping concentration ratio may be controlled to be within a range of about 0.23 to about 0.45.

The growing of the silicon single crystal may further include injecting oxygen into the silicon melt. Herein, oxygen may be injected with co-doped boron and phosphorus into the silicon melt. The initial concentration of oxygen may be controlled to be a particular (or, alternatively, predetermined) concentration. For example, the initial concentration of oxygen may be controlled to be within a range of about 1.5E17 atom/cm³ to about 4E17 atom/cm³ (about 3 ppma to about 8 ppma).

The method of manufacturing a wafer may include slicing a silicon single crystal (S903). The silicon single crystal grown in the cylinder shape may be thinly sliced into a disk shape to have a particular (or, alternatively, predetermined) angle in the axial direction. For example, the silicon single crystal may be sliced at a right angle to the axial direction of the silicon single crystal. The silicon single crystal may be sliced using a diamond blade, etc. The diamond blade may be controlled, for example by a device such as electronic device 1000 shown in FIG. 10 which may operate an actuator (e.g., a servo actuator) to perform the slicing.

The method of manufacturing a wafer, according to the inventive concepts, includes lapping the silicon single crystal (S905). The sliced wafer may be planarized by lapping. The sliced wafer has a rough surface, which may become a reason for defects. The surface of the wafer may be planarized by lapping both sides of the wafer at the same time using a lapping apparatus. The lapping apparatus may be controlled, for example by a device such as electronic device 1000 shown in FIG. 10 which may operate an actuator (e.g., a servo actuator) to perform the lapping. Additionally, an effect that a wafer having a desired thickness may be produced undergoing a lapping process, may be achieved. After the wafer is lapped, the wafer may be cleaned using an etching process.

The method of manufacturing a silicon single crystal, according to the inventive concepts, may include a polishing process of the silicon single crystal (S907). The wafer may be precisely processed through the polishing process. Herein, the polishing process may be a chemical-mechanical polishing (CMP) process. By polishing a surface of the wafer using polishing liquids and polishing apparatus, a highly miniaturized, fined, and precise wafer may be produced. The polishing process may be performed based on a device such as electronic device 1000 shown in FIG. 10 operating one or more devices (e.g., one or more servo actuators associated with a polishing apparatus, one or more polishing liquid supply valves, etc.).

Still referring to FIG. 9, a wafer manufactured at S900 may be incorporated into a manufactured semiconductor device at S909. Such incorporating may include dicing the wafer, etching one or more portions of the wafer, forming one or more layers, structures, or the like on the wafer, or any combination thereof. Such incorporating may be performed based on a device such as electronic device 1000 shown in FIG. 10 operating one or more devices (e.g., operating one or more devices to perform etching, deposition of one or more layers, or the like).

Still referring to FIG. 9, a semiconductor device manufactured at S909 may be incorporated into a manufactured electronic device at S911. Such an electronic device may include, for example, an electronic device having the structure of an electronic device 1000 as shown in FIG. 10. For example, a manufactured electronic device may be or may include electronic device 1000 as shown in FIG. 10. Such an electronic device may be a mobile system or a system that transmits or receives information. In some example embodiments, the mobile system may be a PDA, a portable computer, a web tablet, a wireless phone, a mobile phone, a digital music player, or a memory card. Such incorporating at S911 may include attaching the semiconductor device to one or more other components of the electronic device and electrically coupling the semiconductor device thereto to complete assembly of the electronic device. Such incorporating may be performed based on a device such as electronic device 1000 shown in FIG. 10 operating one or more devices (e.g., operating one or more devices to perform coupling of electronic device components, or the like). In some example embodiments, the manufacturing at S911 may include incorporating multiple semiconductor devices manufactured at S909 and/or incorporating devices manufactured from multiple wafers manufactured at S900 into a single manufactured electronic device.

FIG. 10 is a diagram schematically illustrating an electronic device 1000 according to some example embodiments. The electronic device 1000 may be configured to implement one or more operations of any of the methods according to any of the example embodiments, including any of the operations of the methods shown in FIGS. 1 and 9. The electronic device 1000 may include a wafer manufactured according to any of the methods according to any of the example embodiments.

The electronic device 1000 may include a processor 1010, an input/output device 1020, a memory device 1030, and an interface 1040. The electronic device 1000 may be a mobile system or a system that transmits or receives information. In some example embodiments, the mobile system may be a PDA, a portable computer, a web tablet, a wireless phone, a mobile phone, a digital music player, or a memory card. The processor 1010 is for controlling an execution program in the electronic device 1000, and may include a microprocessor, a digital signal processor, a microcontroller, or a device similar thereto. The processor 1010 may include a semiconductor device according to some example embodiments according to the technical concept of the present inventive concepts. For example, the processor 1010 may include at least one semiconductor device which may include a wafer manufactured according to any of the example embodiments, including for example a wafer manufactured at S900 in the method shown in FIG. 9.

The input/output device 1020 may be used to input or output data of the electronic device 1000. The electronic device 1000 may be connected to an external device, for example, a personal computer or a network, by using the input/output device 1020, and may exchange data with an external device. The input/output device 1020 may be, for example, a keypad, a keyboard, or a display.

The memory device 1030 may store codes and/or data for an operation of the processor 1010 or store data processed by the processor 1010. The memory device 1030 may include a semiconductor device according to some example embodiments according to the technical concept of the present inventive concepts. For example, the memory device 1030 may include at least one semiconductor device which may include a wafer manufactured according to any of the example embodiments, including for example a wafer manufactured at S900 in the method shown in FIG. 9.

The interface 1040 may be a data transmission path between the electronic device 1000 and another external device. The processor 1010, the input/output device 1020, the memory device 1030, and the interface 1040 may communicate with each other via bus 1050. The electronic device 1000 may be used in a mobile phone, an MP3 player, a navigation device, a portable multimedia player (PMP), a solid-state disk (SSD), or household appliances.

As described herein, any devices, systems, units, circuits, controllers, processors, and/or portions thereof according to any of the example embodiments (including, for example, the electronic device 1000, the processor 1010, the input/output device 1020, the memory device 1030, the interface 1040, any portion thereof, or the like) may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods according to any of the example embodiments.

Hitherto, some example embodiments have been described with reference to the figures and examples. Some example embodiments have been described using specific terms in this specification, but they are only used for the purpose of explaining the technical idea of the present inventive concepts and are not used to limit the scope of the present inventive concepts described in the meaning or claims. It should be understood that various changes, modifications, and other equivalent example embodiments can be made by one ordinary skilled in the art. Therefore, the true scope of technical protection of the inventive concepts should be determined by the technical spirit of the attached claims.

While the inventive concepts have been particularly shown and described with reference to some example embodiments thereof, it will be understood that various changes in form and details may be made therein without departing from the spirit and scope of the following claims.

What is claimed is:

1. A method of manufacturing a silicon single crystal, the method comprising:
preparing a silicon melt; and
growing the silicon single crystal based on co-doping boron and phosphorus into the silicon melt,
wherein, in the growing of the silicon single crystal, the silicon single crystal is grown based on
controlling a doping concentration ratio, which is a ratio of an initial concentration of phosphorus to an initial concentration of boron, to be a particular ratio, and
controlling the initial concentration of boron to be within a range of about 8.0E12 atom/cm³ to about 1.5E13 atom/cm³.

2. The method of claim 1,
wherein the doping concentration ratio is controlled to be within a range of about 0.23 to about 0.45.

3. The method of claim 1,
wherein the doping concentration ratio is controlled to be within a range of about 0.35 to about 0.45.

4. The method of claim 1,
wherein the growing of the silicon single crystal is carried out by a Czochralski method process.

5. The method of claim 1,
wherein the growing of the silicon single crystal further includes controlling a concentration of oxygen injected into the silicon melt.

6. The method of claim 5,
wherein the concentration of oxygen is controlled to be within a range of about 1.5E17 atom/cm³ to about 4E17 atom/cm³.

7. The method of claim 1,
wherein the silicon single crystal is a p-type silicon single crystal having a resistivity of at least 1000 Ω·cm.

8. A method of manufacturing a silicon single crystal, the method comprising:
forming a silicon melt based on melting a polycrystal silicon in a quartz crucible in a chamber;
controlling resistivity distribution based on co-doping boron and phosphorus into the silicon melt; and
growing the silicon single crystal based on rotating the quartz crucible,
wherein, in the controlling of the resistivity distribution of the silicon single crystal, the resistivity distribution of the silicon single crystal is controlled based on
controlling a doping concentration ratio, which is a ratio of an initial phosphorus concentration to an initial concentration of boron, to be a particular ratio, and
controlling the initial concentration of boron to be within a range of about 8.0E12 atom/cm³ to about 1.5E13 atom/cm³.

9. The method of claim 8,
wherein, in the controlling of the resistivity distribution of the silicon single crystal, the doping concentration ratio is controlled to be within a range of about 0.23 to about 0.45.

10. The method of claim 8,
wherein, in the controlling of the resistivity distribution of the silicon single crystal, the doping concentration ratio is controlled to be within a range of about 0.35 to about 0.45.

11. The method of claim 8,
wherein the controlling of the resistivity distribution of the silicon single crystal further includes controlling a concentration of oxygen injected into the silicon melt.

12. The method of claim 11,
wherein the concentration of oxygen is controlled to be within a range of about 1.5E17 atom/cm³ to about 4E17 atom/cm³.

13. The method of claim 8,
wherein the silicon single crystal is a p-type silicon single crystal having resistivity of at least 1000 Ω·cm.

14. The method of claim 8,
wherein the growing of the silicon single crystal is carried out by a Czochralski method process.

15. A method of manufacturing a wafer, the method comprising:
growing a silicon single crystal;
slicing the silicon single crystal;
lapping the silicon single crystal; and
polishing the silicon single crystal,
wherein, in the growing of the silicon single crystal, the silicon single crystal is grown based on
controlling a doping concentration ratio, which is a ratio of an initial concentration of phosphorus to an initial concentration of boron, to be a particular ratio, and
controlling the initial concentration of boron to be within a range of about 8.0E12 atom/cm³ to about 1.5E13 atom/cm³.

16. The method of claim 15,
wherein the doping concentration ratio is within a range of about 0.23 to about 0.45.

17. The method of claim 15,
wherein the growing of the silicon single crystal further includes controlling a concentration of oxygen injected into a silicon melt.

18. The method of claim 17,
wherein the concentration of oxygen is controlled to be within a range of about 1.5E17 atom/cm³ to about 4E17 atom/cm³.

19. The method of claim 17,
wherein the growing of the silicon single crystal is carried out by a Czochralski method process.

20. The method of claim 17,
wherein the silicon single crystal is a p-type silicon single crystal having a resistivity of at least 1000 Ω·cm.
